(19) United States
(12) Patent Application Publication
(10) Pub. No.: US 2026/0239956 A1
(43) Pub. Date: Aug. 13, 2026

(54) METAL WIRING WITH INCREASED THERMAL CONDUCTIVITY

(71) Applicant: International Business Machines Corporation, Armonk, NY (US)

(72) Inventors: Kevin Wayne Brew, Niskayuna, NY (US); Darsith Jayachandran, Menands, NY (US); Prabudhya Roy Chowdhury, Albany, NY (US); Christopher J. Penny, Saratoga Springs, NY (US); Koichi Motoyama, Clifton Park, NY (US)

(21) Appl. No.: 19/051,827

(22) Filed: Feb. 12, 2025

(51) Int. Cl. H01L 23/532; H01L 23/522; H01L 23/528

(52) U.S. Cl. CPC H10W 20/48; H10W 20/42; H10W 20/435

(57) ABSTRACT

A semiconductor device is provided that includes metal wiring located on at least one side (e.g., the frontside, the backside or the frontside and the backside) of a substrate, where the metal wires have increased thermal conductivity. The increased thermal conductivity is obtained in the present application by an electrically insulating and thermally conductive dielectric liner that is disposed on at least a sidewall of each of the metal wires and on a surface of the substrate. The electrically insulating and thermally conductive dielectric liner provides a path for heat dissipation within the semiconductor device.

### BACKGROUND

The present application relates to semiconductor technology, and more particularly to a semiconductor device including metal wiring that has increased thermal conductivity.

Generally, frontside back-end-of-the-line (BEOL) structures include a plurality of circuits which form an integrated circuit fabricated on a front side of a substrate including a front-end-of-the-line (FEOL) level. A complex network of signal paths will normally be routed to connect the circuit elements distributed on the substrate. Efficient routing of these signals across the device requires formation of multilevel or multilayered schemes, such as, for example, single or dual damascene metal wiring. Within typical frontside BEOL structures, metal vias run perpendicular to a substrate and metal lines run parallel to the substrate. The metal wiring is embedded within an interlayer dielectric layer.

Backside power delivery refers to a novel technique where power supply lines (in the form of, for example, metal wires and/or metal vias) located in a backside BEOL structure are routed on the backside of the substrate, rather than the traditional frontside. Backside power delivery offers several advantages, including increased logic density and improved power and performance (better signal integrity, reduced noise and improved overall chip performance). Backside BEOL structure also include metal wiring that is embedded within an interlayer dielectric layer.

### SUMMARY

A semiconductor device is provided that includes metal wiring located on at least one side (e.g., the frontside, the backside or the frontside and the backside) of a substrate, where the metal wires have increased thermal conductivity. The increased thermal conductivity is obtained in the present application by an electrically insulating and thermally conductive dielectric liner that is disposed on at least a sidewall of each of the metal wires and on a surface of the substrate. The electrically insulating and thermally conductive dielectric liner provides a path for heat dissipation within the semiconductor device.

In one embodiment of the present application, the semiconductor device includes a plurality of metal wires located on a substrate, an electrically insulating and thermally conductive dielectric liner located on at least a sidewall of each metal wire of the plurality of metal wires and along a surface of the substrate, and an interlayer dielectric (ILD) layer located at least adjacent to each metal wire of the plurality of metal wires, and on the electrically insulating and thermally conductive dielectric liner.

In another embodiment of the present application, the semiconductor device includes a plurality of metal lines and a top metal via structure located on a substrate, an electrically insulating and thermally conductive dielectric liner located on a sidewall and a topmost surface of each metal line of the plurality of metal lines, a sidewall of the top metal via structure, and along a surface of the substrate, an ILD layer located adjacent to each metal line of the plurality of metal lines and the top metal via structure, and on the electrically insulating and thermally conductive dielectric liner, and an upper level metal line connected to the top metal via structure.

### BRIEF DESCRIPTION OF THE DRAWINGS

FIG. 1 is a cross sectional view of an exemplary semiconductor device in accordance with an embodiment of the present application.

FIG. 2A is a top down view of an initial structure that can be used in providing an exemplary semiconductor device in accordance with an embodiment of the present application, the initial structure including metal wiring in the form of metal lines and a top metal via structure located on a substrate.

FIG. 2B is a cross sectional view of the initial structure through cut X-X illustrated in

FIG. 2A.

FIG. 3A is a top down view of the initial structure illustrated in FIG. 2A after forming an electrically insulating and thermally conductive dielectric liner along a sidewall and a topmost surface of the metal wiring.

FIG. 3B is a cross sectional view of the structure through cut X-X illustrated in FIG. 3A.

FIG. 4A is a top down view of the structure illustrated in FIG. 3A after forming an

ILD layer on the electrically insulating and thermally conductive dielectric liner and above the metal wiring.

FIG. 4B is a cross sectional view of the structure through cut X-X illustrated in FIG. 4A.

FIG. 5A is a top down view of the structure illustrated in FIG. 4A after revealing a topmost surface of the top metal via structure.

FIG. 5B is a cross sectional view of the structure through cut X-X illustrated in FIG. 5A.

FIG. 6A is a top down view of the structure illustrated in FIG. 5A after forming an upper level metal line.

FIG. 6B is a cross sectional view of the structure through cut X-X illustrated in FIG. 6A.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Air gap features, such as those typically found in semiconductor devices containing subtractive metal wires, are generally sought after for their low dielectric constant property. However, heat does not travel well through such air gap features, and at the levels containing the subtractive metal wires. In current semiconductor devices in which air gap features are present (and in those in which no air gap features are present) there is a need to dissipate heat from the semiconductor device.

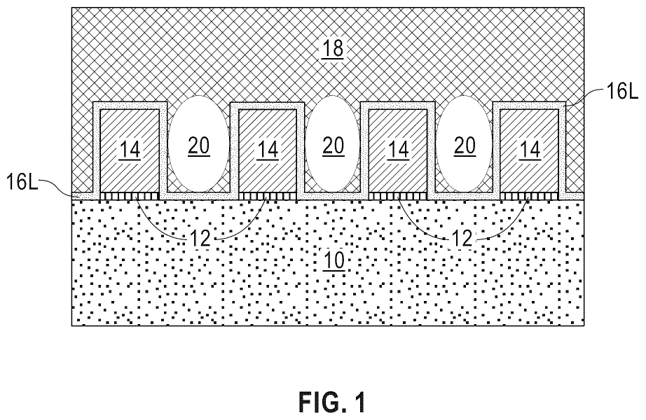

In the present application and as is illustrated in FIG. 1, the above heat dissipation issue can be substantially reduced and even eliminated, by forming a dielectric liner that is electrically insulating, yet thermally conductive (hereinafter this dielectric liner is referred to as electrically insulating and thermally conductive dielectric liner 16L), on physically exposed surfaces (e.g., sidewall and topmost) of metal wires 14 that are located on a side of substrate 10. Each metal wire 14 can be spaced apart from the substrate 10 by diffusion barrier layer 12. In some embodiments, the diffusion barrier layer 12 can be omitted and each metal wiring 14 is located directly on a surface of the substrate 10.

Notably, FIG. 1 illustrates a semiconductor device is accordance with an embodiment of the present application which includes a plurality of metal wires 14 located on substrate 10, electrically insulating and thermally conductive dielectric liner 16L located on at least a sidewall of each metal wire 14 of the plurality of metal wires and along a surface of the substrate 10, and ILD layer 18 located at least adjacent to each metal wire 14 of the plurality of metal wires, and on the electrically insulating and thermally conductive dielectric liner 16L.

The type of metal wire 14 employed in the present application is not limited and can include a metal via, a metal line, a top metal via structure, a top metal line structure or any combination thereof. A top metal via structure is a metal wire that includes at least one metal via located on top of a metal line. A top metal line structure is a metal wire that includes at least one metal line located on top of a metal via. In the embodiment illustrated in FIG. 1, the electrically insulating and thermally conductive dielectric liner 16L is a conformal layer that is located along a sidewall and a topmost surface of each metal wire 14 and it is present along a physically exposed surface of the substrate 10. Although not illustrated in FIG. 1, the electrically insulating and thermally conductive dielectric liner 16L can be removed from a topmost surface of at least one of the metal wires 14. The removal of the electrically insulating and thermally conductive dielectric liner 16L from the topmost surface of at least one of the metal wires 14 allows connection of the revealed metal wire to a next level (i.e., upper level) metal wire. The electrically insulating and thermally conductive dielectric liner 16L can increase the thermal conductivity of the metal wiring 14 by providing a path for heat dissipation within the semiconductor device of the present application. This path can be a continuous path as illustrated in FIG. 1 or a discontinuous path (not shown in FIG. 1) as is the case when the electrically insulating and thermally conductive dielectric liner 16L is removed from the topmost surface of at least one of the metal wires 14.

In the present application and as illustrated in FIG. 1, each metal wire 14 is located on a same level and on a same side of the substrate 10. In the present application, each metal wire 14 can be present on a frontside of the substrate 10 or a backside of the substrate 10. In some embodiments (not shown), frontside metal wires are formed on a frontside of the substrate 10, and backside metal wires are formed on a backside of the substrate 10. In such an embodiment, an electrically insulating and thermally conductive dielectric liner 16L can be formed on the frontside and/or backside metal wires. In such an embodiment, the electrically insulating and thermally conductive dielectric liner 16L can increase the thermal conductivity of the frontside and/or backside metal wiring by providing a path for heat dissipation within the semiconductor device of the present application.

As is illustrated in FIG. 1, ILD layer 18 can be located adjacent to each metal wire 14. In some embodiments, the ILD layer 18 fills in the gaps located between each neighboring pair of metal wires 14. In such embodiments and as illustrated in FIG. 1, air gaps 20 can be present in the ILD layer 18; each air gap 20 can be located between a neighboring pair of metal wires as is illustrated in FIG. 1. Air gaps 20 are typically formed when the pitch between the metal wires 14 is 50 nm or less. In the present application, the term “pitch” defines a distance from one point (e.g., a central point) of one of the metal wires to the same point (e.g., a central point) of a neighboring metal wire. Air gaps 20 have an extremely low dielectric constants in which heat does not readily dissipate there through. The presence of the electrically insulating and thermally conductive dielectric liner 16L in semiconductor devices including air gaps 20 can increase the thermal conductivity of the metal wiring 14 by providing a path for heat dissipation within the semiconductor device of the present application. This path can be a continuous path as illustrated in FIG. 1 or a discontinuous path (not shown in FIG. 1) as is the case when the electrically insulating and thermally conductive dielectric liner 16L is removed from a topmost surface of at least one of the metal wires 14.

In the present application, substrate 10 includes a front-end-of-the-line (FEOL) level and, in some embodiments, a metal level; the FEOL level and the optional metal level are not separately illustrated in the drawings of the present application. In some embodiments, the metal level of substrate 10 can be a middle-of-the line (MOL) level. In other embodiments, the metal level of substrate 10 can be at least one lower interconnect level of a multi-level interconnect structure. In yet further embodiments, the metal level of substrate 10 can be a combination of a MOL level and at least one lower interconnect level of a multi-level interconnect structure. The metal level of substrate 10 can include electrically conductive wiring structures (e.g., metal lines and/or metal vias) embedded in a dielectric material layer. In yet other embodiments, the metal level is omitted from substrate 10. The FEOL level includes one or more semiconductor devices (such as, for example, transistors, resistors and/or capacitors) that can be formed on a semiconductor substrate. In some embodiments, the semiconductor substrate of the FEOL level is present in substrate 10. In other embodiments, the semiconductor substrate of the FEOL level can be partially or entirely removed from the FEOL level. The substrate 10 including the optional metal level and the FEOL level can be formed utilizing materials and techniques that are well known to those skilled in the art.

In the present application, diffusion barrier layer 12 is composed of a diffusion barrier material such as, for example, Ta, TaN, Ti, TiN, Ru, RuN, RuTa, RuTaN, W, WN or any other material that can serve as a barrier to prevent an electrically conductive material from diffusing there through. In some embodiments, a combination of diffusion barrier materials, e.g., Ta/TaN can be employed as the diffusion barrier layer 12. The thickness of the diffusion barrier layer 12 may vary. In one example, the thickness of the diffusion barrier layer 12 is from 0.5 nm to 10 nm. In the present application, the diffusion barrier material that provides the diffusion barrier layer 12 can be formed by a deposition process such as, for example, chemical vapor deposition (CVD), plasma enhanced chemical vapor deposition (PECVD), or physical vapor deposition (PVD).

In the present application, each metal wire 14 is composed an electrically conductive material such as, for example, an electrically conductive metal or an electrically conductive metal alloy. Illustrative examples of electrically conductive metals include, but are not limited to, copper, (Cu), aluminum (Al), tungsten (W), cobalt (Co), ruthenium (Ru), nickel (Ni), iridium (Ir), molybdenum (Mo) or rhodium (Rh). An example of an electrically conductive alloy that can be used in providing each metal wire 14 includes a Ru-Al alloy. In the present application, each metal wire 14 can be formed utilizing a technique such as, for example, single damascene, dual damascene or a subtractive metal wiring forming process (oftentimes referred to as a subtractive metal etch process), that is well known to those skilled in the art. The subtractive metal wiring forming process can use a subtractive metal such as, for example, Ru, which has a higher wire conductivity as compared to conventional Cu wires. Ru wires have a thermal conductivity that is less than about one-third the thermal conductivity of Cu wires. Thus, and in some embodiments, each of the metal wires 14 can be composed of an electrically conductive metal that has a thermal conductivity that is less than copper.

In the present application, the electrically insulating and thermally conductive dielectric liner 16L is composed of an electrically insulating dielectric material that has a thermal conductivity that is greater than 10 W/m/k. In some embodiments, the electrically insulating and thermally conductive dielectric liner 16L is composed of an electrically insulating dielectric material that has a thermal conductivity that is greater than 50 W/m/k, and even greater than 100 W/m/k. Illustrative examples of electrically insulating dielectric material that can be employed as the electrically insulating and thermally conductive dielectric liner 16L include, but are not limited to, diamond-like carbon (DLC), aluminum nitride (AlN) or hydrogenated boron nitride (h-BN). DLC is a class of amorphous carbon materials that display some of the typical properties of a diamond. DLC contain a significant amount of sp³ hybridized carbon atoms. One example of an DLC that can be used in the present application is tetrahedral amorphous carbon. The DLC can be non-hydrogenated or hydrogenated.

The electrically insulating and thermally conductive dielectric liner 16L is a conformal layer. The term “conformal layer” denotes a material layer has a vertical thickness along horizontal surfaces that is substantially the same (i.e., within ±5%) as the lateral thickness along vertical surfaces. The electrically insulating and thermally conductive dielectric liner 16L can be formed by a conformal deposition process, including but not limited to, ALD, CVD, PECVD or PVD. It is noted that following the deposition of the electrically insulating and thermally conductive dielectric liner 16L, no directional etching process is used to remove the electrically insulating and thermally conductive dielectric liner 16L from the surface of substrate 10 and from the top of each of the metal wire 14.

In the present application, ILD layer 18 can be composed of any interconnect dielectric material including, for example, silicon oxide (SiOₓ), silicon nitride, undoped silicate glass (USG), fluorosilicate glass (FSG), borophosphosilicate glass (BPSG), a spin-on low-k dielectric, a chemical vapor deposition (CVD) low-k dielectric, or any combination thereof. The term “low-k” as used throughout the present application denotes a dielectric material that has a dielectric constant of less than 4.0 (all dielectric constants mentioned herein are measured in a vacuum unless otherwise noted). The ILD layer 18 can be formed by a deposition process such as, for example, CVD, PECVD or spin-on coating. In some embodiments, not shown in FIG. 1, a planarization process such as, for example, chemical mechanical planarization (CMP) or grinding can be used to reveal a topmost surface of at least one of the metal wires 14 and thereafter an upper level metal wire is formed in connection with the revealed at least one metal wire. In this instance, at least one of the metal wires 14 has a topmost surface devoid of the electrically insulating and thermally conductive dielectric liner 16L and this metal wire is connected to an upper level metal wire.

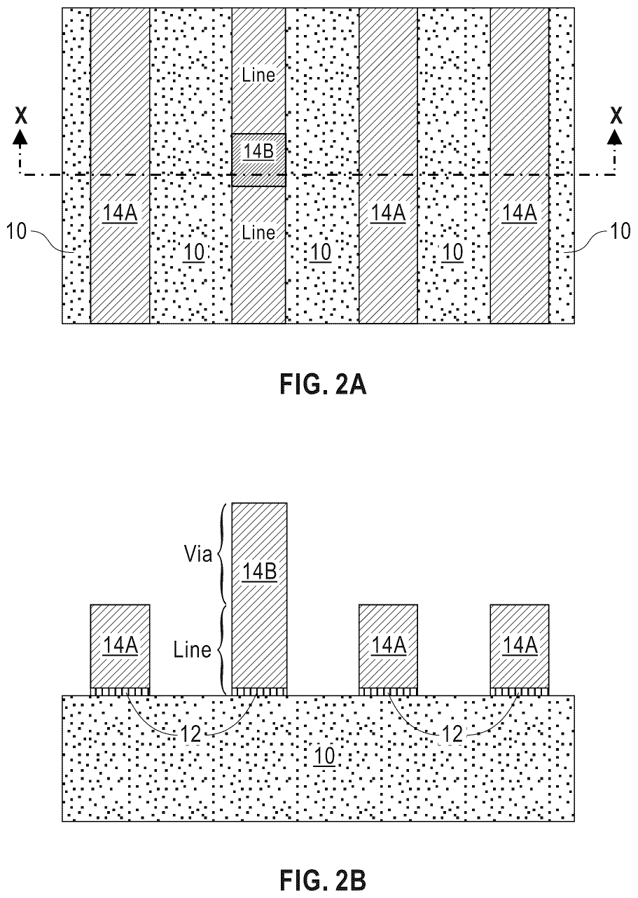

Reference is now made to FIGS. 2A, 2B, 3A, 3B, 4A, 4B, 5A, 5B, 6A and 6B which illustrate processing steps that can used in providing an exemplary semiconductor device in accordance with an embodiment of the present application. Within the exemplary embodiment depicted in FIGS. 2A-6B, elements as defined above are employed. In the illustrated exemplary embodiment, metal wires in the form of metal lines 14A and a top metal via structure 14B are employed for illustrative purposes only.

Notably, and referring to FIGS. 2A-2B, there are illustrated an initial structure that can be used in providing an exemplary semiconductor device in accordance with the present application. The initial structure illustrated in FIGS. 2A-2B includes metal lines 14A and top metal via structure 14B as metal wires. Each of these metal wires are located on a same level and same side of substrate 10. In the exemplary embodiment of the present application, the top metal via structure 14B and each metal line 14A can be present on a frontside or a backside of the substrate 10. In some embodiments (not shown), a frontside top metal via structure and frontside metal lines are formed on a frontside of the substrate 10, and a backside top metal via structure and backside metal lines are formed on a backside of the substrate 10.

In some embodiments, diffusion barrier layer 12 can be present between the substrate 10 and each of the metal wires (i.e., top metal via structure 14B and metal lines 14A) that are present on substrate 10. The diffusion barrier layer 12 and the substrate 10 are as defined above with respect to the embodiment depicted in FIG. 1. The top metal via structure 14B and the metal lines 14A are types of metal wires that can be used. Although these specific types are described and illustrated in FIGS. 2A-6B, the present application contemplates using other types of metal wires (as defined above for metal wires 14 depicted in FIG. 1) instead of the top metal via structure 14B and the metal lines 14A illustrated in this exemplary embodiment of the present application. The top metal via structure 14B and the metal lines 14A are composed of an electrically conductive metal or electrically conductive metal alloy as defined above for metal wires 14. In some embodiments, the top metal via structure 14B and the metal lines 14A are composed of an electrically conductive metal that has a thermal conductivity that is less than metal wires that are composed of copper.

In the exemplary embodiment, the top metal via structure 14B and the metal lines 14A are typically formed utilizing a subtractive metal wiring forming process. In some embodiments, the subtractive metal wiring forming process includes depositing a blanket layer of diffusion barrier material on substrate 10. After the depositing the blanket layer of diffusion barrier material on substrate 10, a blanket layer of an electrically conductive material is deposited on the blanket layer of diffusion barrier material. The depositing of the blanket layer of electrically conductive material can include, but is not limited to, CVD, PECVD, PVD, atomic layer deposition (ALD), sputtering or plating. After forming the material stack of the blanket layer of diffusion barrier material and the blanket layer of electrically conductive material, initial metal lines are formed utilizing a first patterning step. The first patterning step can include any patterning process including, for example, lithographic patterning. The etch used during the first patterning step etches through the material stack of the blanket layer of diffusion barrier material and the blanket layer of electrically conductive material and stops on a surface of substrate 10. Next, a second patterning step is used to reduce the height of each of the initial metal lines forming the metal lines 14A and the top metal via structure 14B. It is noted that the second patterning step includes the use of a mask that covers (i.e., protects) a portion of one of the initial metal lines, and then an etch is used to reduce the height of each of the initial lines. The portion of the initial metal line that is covered to by the mask provides the via portion of the top metal via structures 14B.

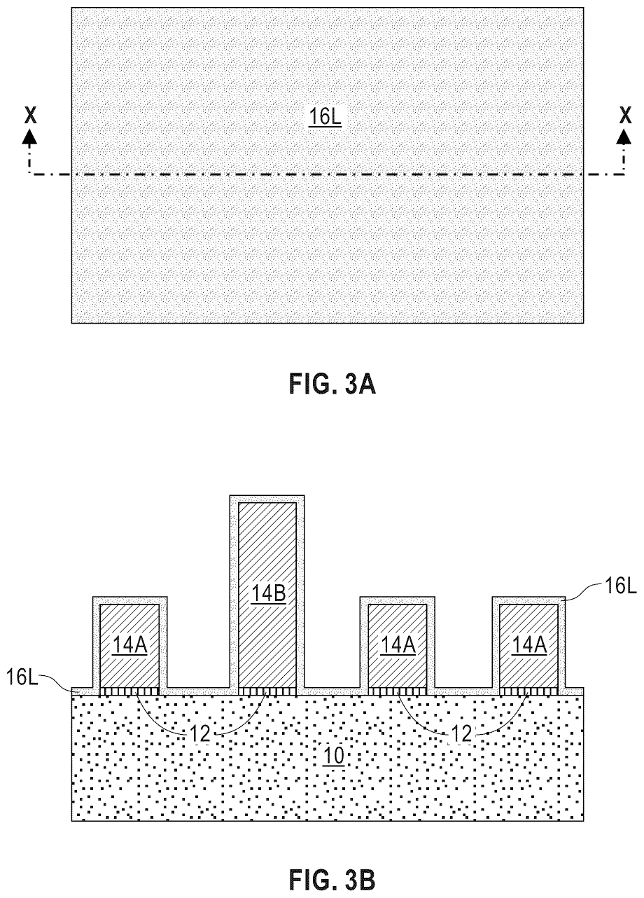

Next, and as illustrated in FIGS. 3A-3B, electrically insulating and thermally conductive dielectric liner 16L is formed along a sidewall and a topmost surface of the top metal via structure 14B and the metal lines 14A. The electrically insulating and thermally conductive dielectric liner 16L is also formed along a physically exposed surface of the substrate 10 as is illustrated in FIG. 3B. The electrically insulating and thermally conductive dielectric liner 16L is composed of an electrically insulating dielectric material as defined above. The electrically insulating and thermally conductive dielectric liner 16L is a conformal layer as defined above. The electrically insulating and thermally conductive dielectric liner 16L can be formed by a conformal deposition process as mentioned above. It is again noted that following the deposition of the electrically insulating and thermally conductive dielectric liner 16L, no directional etching process is used to remove the electrically insulating and thermally conductive dielectric liner 16L from the surface of substrate 10 and from the top of each of the metal features (i.e., metal lines 14A and top metal via structure 14B).

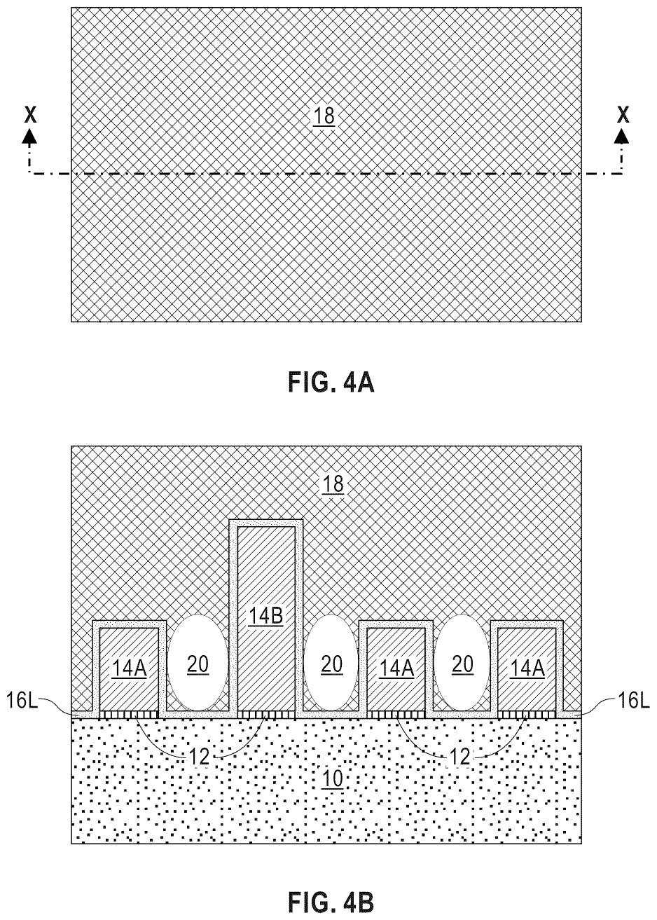

Next, and as is illustrated in FIGS. 4A-4B, ILD layer 18 is formed on the electrically insulating and thermally conductive dielectric liner 16L and above the metal lines 14A and the top metal via structure 14B. ILD layer 18 can be composed of any interconnect dielectric material as defined above. ILD layer 18 can be formed by a deposition process as mentioned previously in the present application. In the illustrated embodiment shown in FIG. 4B, the ILD layer 18 fills in the gaps that are located between the metal lines 14A and the top metal via structure 14B.

In some embodiments and as illustrated in FIG. 4B, air gaps 20 can be present in a lower portion of the ILD layer 18. When present, air gaps 20 are typically present between each of the metal wires that are located adjacent on the substrate 10. The height of the air gaps 20 can vary. In some embodiments and as illustrated in FIG. 4B, the height of the air gaps 20 is substantially equal to a combined height of the metal line 14A and the diffusion barrier layer 12.

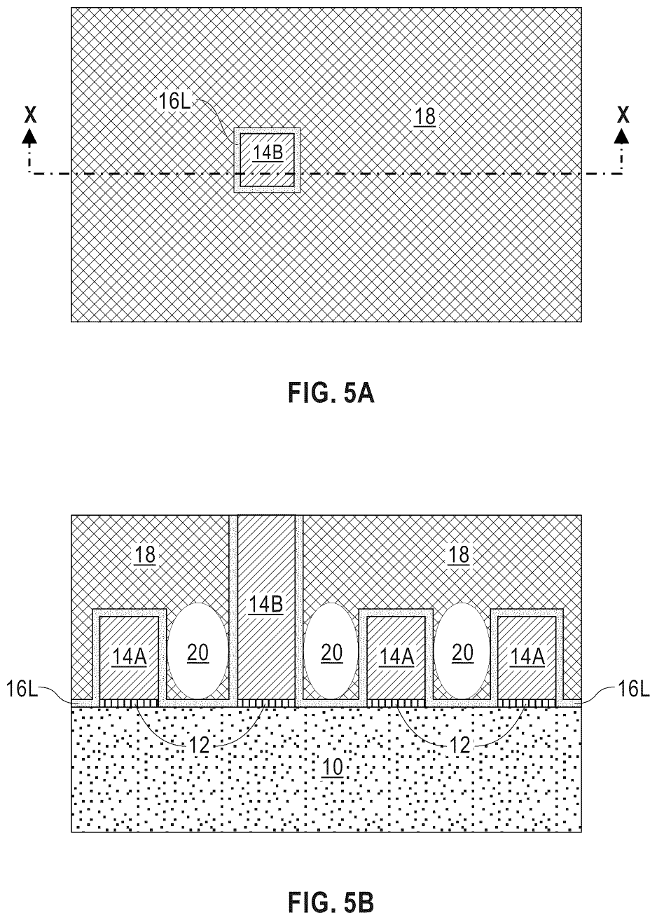

Next, and as is illustrated in FIGS. 5A-5B, the topmost surface of the top metal via structure 14B is reveled. The revealing of the topmost surface of the top metal via structure 14B includes a planarization process such as, for example, CMP or grinding, that removes an upper portion of the ILD layer 18 that is located above the top metal via structure 14B as well as the electrically insulating and thermally conductive dielectric liner 16L that is located on the topmost surface of the top metal via structure 14B. Although the electrically insulating and thermally conductive dielectric liner 16L is removed from the top metal via structure 14B, each remaining portion of the electrically insulating and thermally conductive dielectric liner 16L provides its own path for heat dissipation.

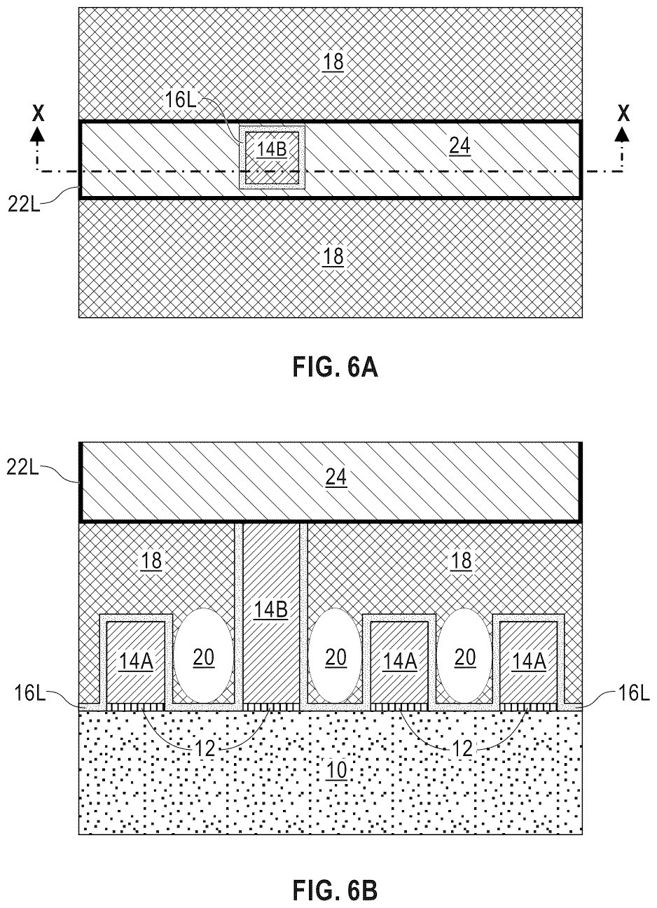

In some embodiments, and following the removal of the upper portion of the ILD layer 18, an upper level metal line 24 as is illustrated in FIGS. 6A-6B is formed. Although an upper level metal line 24 is described and illustrated, the upper level metal line 24 can be replaced with another type of metal wire. The upper level metal line 24 is formed in an upper level ILD layer (not shown) that is formed on the ILD layer 18 and above the top metal via structure 14B and the metal lines 14A. The upper level ILD layer can include one of the interconnect dielectric materials mentioned above for the ILD layer 18. The interconnect dielectric material that provides the upper level ILD layer can be compositionally the same as, or compositionally different from, the interconnect dielectric material that provides the ILD layer 18. The upper level ILD layer can be formed by a deposition process including deposition processes mentioned above in forming the ILD layer 18.

In some embodiments, an upper level diffusion barrier liner 22L as illustrated in FIGS. 6A-6B can be present. When present, the upper level diffusion barrier liner 22L can be present along a sidewall and bottommost surface of the upper level metal line 24. In other embodiments, upper level diffusion barrier liner 22L can be omitted. If present, the upper level diffusion barrier liner 22L can be composed of a diffusion barrier material such as, for example, Ta, TaN, Ti, TiN, Ru, RuN, RuTa, RuTaN, W, WN or any other material that can serve as a barrier to prevent an electrically conductive material from diffusing there through. In some embodiments, a combination of diffusion barrier materials, e.g., Ta/TaN can be employed as the upper level diffusion barrier liner 22L. The thickness of the upper level diffusion barrier liner 22L may vary. In one example, the thickness of the upper level diffusion barrier liner 22L is from 0.5 nm to 10 nm.

The upper level metal line 24 is composed of an electrically conductive metal or an electrically conductive metal alloy as defined above for metal wires 14.

The upper level metal line 24 can be formed by a metallization process in which an opening (e.g., line opening) is first formed into the upper level ILD layer. The opening can be formed by a lithographic patterning process including lithography and etching. A layer of diffusion barrier material can optionally be deposited into the opening, followed by the deposition of an electrically conductive metal or electrically conductive metal alloy as mentioned above. A planarization process such as, for example, CMP, can then be used to remove a portion of the as-deposited layer of diffusion barrier material and a portion of the as-deposited electrically conductive metal or electrically conductive metal alloy that is formed outside of the opening and on top of the upper level ILD layer. A portion of the as-deposited layer of diffusion barrier and a portion of the as-deposited electrically conductive metal or electrically conductive metal alloy remains in the opening after this planarization process. The remaining portion of the as-deposited layer of diffusion barrier provides the upper level diffusion barrier liner 22L and the remaining portion of the as-deposited electrically conductive metal or electrically conductive metal alloy provides the upper level metal line 24. It is noted that the upper level metal line 24 lies perpendicular to the metal lines 14A and the line portion of the top metal via structure 14B.

Notably, FIG. 6B illustrates a semiconductor device in accordance with an exemplary embodiment of the present application that includes a plurality of metal lines (e.g., metal line 14A) and top metal via structure 14B located on substrate 10, electrically insulating and thermally conductive dielectric liner 16L located on a sidewall and a topmost surface of each metal line 14A of the plurality of metal lines, a sidewall of the top metal via structure 14B, and along a surface of the substrate 10, ILD layer 18 located adjacent to each metal line 14A of the plurality of metal lines and the top metal via structure 14B, and on the electrically insulating and thermally conductive dielectric liner 16L, and an upper level metal line 24 connected to the top metal via structure 14B. Embodiments include air gaps 20 present in the ILD layer 18.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a plurality of metal wires located on a substrate;
an electrically insulating and thermally conductive dielectric liner located on at least a sidewall of each metal wire of the plurality of metal wires and along a surface of the substrate; and
an interlayer dielectric (ILD) layer located at least adjacent to each metal wire of the plurality of metal wires, and on the electrically insulating and thermally conductive dielectric liner.

2. The semiconductor device of claim 1, wherein each metal wire of the plurality of metal wires is a metal via, a metal line, a top metal via structure, a top metal line structure or any combination thereof.

3. The semiconductor device of claim 1, wherein the substrate comprises at least a front-end-of-the-line level, and the plurality of metal wires are located on a frontside of the substrate.

4. The semiconductor device of claim 1, wherein the substrate comprises at least a front-end-of-the-line level, and the plurality of metal wires are located on a backside of the substrate.

5. The semiconductor device of claim 1, further comprising a diffusion barrier layer located between each metal wire of the plurality of metal wires and the substrate.

6. The semiconductor device of claim 1, further comprising an air gap located in the ILD layer, and between each metal wire of the plurality of metal wires.

7. The semiconductor device of claim 1, wherein the electrically insulating and thermally conductive dielectric liner is present on a topmost surface of at least one of the metal wires of the plurality of metal wires.

8. The semiconductor device of claim 1, wherein each metal wire of the plurality of metal wires is composed of an electrically conductive metal that has a thermal conductivity that is less than copper.

9. The semiconductor device of claim 1, wherein the electrically insulating and thermally conductive dielectric liner is composed of an electrically insulating dielectric material having a thermal conductivity greater than 10 W/m/k.

10. The semiconductor device of claim 1, wherein the electrically insulating and thermally conductive dielectric liner is composed of an electrically insulating dielectric material having a thermal conductivity greater than 100 W/m/k.

11. The semiconductor device of claim 1, wherein the electrically insulating and thermally conductive dielectric liner comprises diamond-like carbon (DLC), aluminum nitride (AlN) or hydrogenated boron nitride (h-BN).

12. The semiconductor device of claim 1, wherein at least one of the metal wires of the plurality of metal wires has a topmost surface that is devoid of the electrically insulating and thermally conductive dielectric liner.

13. The semiconductor device of claim 12, wherein the at least one of the metal wires of the plurality of metal wires that has the topmost surface devoid of the electrically insulating and thermally conductive dielectric liner is connected to an upper level metal wire.

14. A semiconductor device comprising:
a plurality of metal lines and a top metal via structure located on a substrate;
an electrically insulating and thermally conductive dielectric liner located on a sidewall and a topmost surface of each metal line of the plurality of metal lines, a sidewall of the top metal via structure, and along a surface of the substrate;
an interlayer dielectric (ILD) layer located adjacent to each metal line of the plurality of metal lines and the top metal via structure, and on the electrically insulating and thermally conductive dielectric liner; and
an upper level metal line connected to the top metal via structure.

15. The semiconductor device of claim 14, wherein the substrate comprises at least a front-end-of-the-line level, and the plurality of metal lines and the top metal via structure are located on a frontside of the substrate.

16. The semiconductor device of claim 14 wherein the substrate comprises at least a front-end-of-the-line, and the plurality of metal lines and the top metal via structure are located on a backside of the substrate.

17. The semiconductor device of claim 14, further comprising a diffusion barrier layer located between each metal line of the plurality of metal lines and the substrate, and between the top metal via structure and the substrate.

18. The semiconductor device of claim 14, further comprising an air gap located in the ILD layer.

19. The semiconductor device of claim 14, wherein each metal line of the plurality of metal lines and the top metal via structure are composed of an electrically conductive metal that has a thermal conductivity that is less than copper.

20. The semiconductor device of claim 14, wherein the electrically insulating and thermally conductive dielectric liner is composed of an electrically insulating dielectric material having a thermal conductivity greater than 10 W/m/k.
